(19) United States
(12) Patent Application Publication
(10) Pub. No.: US 2026/0128096 A1
(43) Pub. Date: May 7, 2026

(54) BIAS CIRCUIT FOR NON-VOLATILE MEMORY ARRAY IN A NEURAL NETWORK

(71) Applicant: Silicon Storage Technology, Inc., San Jose, CA (US)

(72) Inventors: HOA VU, Milpitas, CA (US); HIEU VAN TRAN, San Jose, CA (US); THUAN VU, San Jose, CA (US); STANLEY HONG, San Jose, CA (US); STEPHEN TRINH, San Jose, CA (US)

(21) Appl. No.: 18/991,295

(22) Filed: Dec. 20, 2024

Related U.S. Application Data
(60) Provisional application No. 63/716,175, filed on Nov. 4, 2024.

(51) Int. Cl. G11C 16/08; G11C 16/04; G11C 16/26

(52) U.S. Cl. CPC G11C 16/08; G11C 16/0433; G11C 16/26

(57) ABSTRACT

In one example, a system comprises an array of non-volatile memory cells arranged in rows and columns, wherein each non-volatile memory cell comprises a word line terminal and a bit line terminal; and a row circuit to receive a row address and a bias voltage and to output the bias voltage when the row address corresponds to a row of the array associated with the row circuit, wherein the bias voltage is provided to terminals of non-volatile memory cells in the row of the array associated with the row circuit.

### PRIORITY CLAIM

This application claims priority to U.S. Provisional Patent Application No. 63/716,175, filed on Nov. 4, 2024, and titled “Bias Circuit for Non-Volatile Memory Array in Neural Network,” which is incorporated by reference herein.

### FIELD OF THE INVENTION

Numerous examples are disclosed of a bias circuit for a non-volatile memory array in a neural network.

### BACKGROUND OF THE INVENTION

Artificial neural networks mimic biological neural networks (the central nervous systems of animals, in particular the brain) and are used to estimate or approximate functions that can depend on a large number of inputs and are generally unknown. Artificial neural networks generally include layers of interconnected “neurons” which exchange messages between each other.

FIG. 1 illustrates an artificial neural network, where the circles represent the inputs or layers of neurons. The connections (called synapses) are represented by arrows and have numeric weights that can be tuned based on experience. This makes neural networks adaptive to inputs and capable of learning. Typically, neural networks include a layer of multiple inputs. There are typically one or more intermediate layers of neurons, and an output layer of neurons that provide the output of the neural network. The neurons at each level individually or collectively make a decision based on the received data from the synapses.

One of the major challenges in the development of artificial neural networks for high-performance information processing is a lack of adequate hardware technology. Indeed, practical neural networks rely on a very large number of synapses, enabling high connectivity between neurons, i.e., a very high computational parallelism. In principle, such complexity can be achieved with digital supercomputers or graphics processing unit clusters. However, in addition to high cost, these approaches also suffer from mediocre energy efficiency as compared to biological networks, which consume much less energy primarily because they perform low-precision analog computation. CMOS analog circuits have been used for artificial neural networks, but most CMOS-implemented synapses have been too bulky given the high number of neurons and synapses.

Applicant previously disclosed an artificial (analog) neural network that utilizes one or more non-volatile memory arrays as the synapses in U.S. Patent Application Publication 2017/0337466A1, which is incorporated by reference. The non-volatile memory arrays operate as an analog neural memory and comprise non-volatile memory cells arranged in rows and columns. The neural network includes a first plurality of synapses configured to receive a first plurality of inputs and to generate therefrom a first plurality of outputs, and a first plurality of neurons configured to receive the first plurality of outputs. The first plurality of synapses includes a plurality of memory cells, wherein each of the memory cells includes spaced apart source and drain regions formed in a semiconductor substrate with a channel region extending there between, a floating gate disposed over and insulated from a first portion of the channel region and a non-floating gate disposed over and insulated from a second portion of the channel region. Each of the plurality of memory cells store a weight value corresponding to a number of electrons on the floating gate. The plurality of memory cells multiply the first plurality of inputs by the stored weight values to generate the first plurality of outputs.

### Non-Volatile Memory Cells

Non-volatile memories are well known. For example, U.S. Pat. No. 5,029,130 (“the '130 patent”), which is incorporated herein by reference, discloses an array of split gate non-volatile memory cells, which are a type of flash memory cells. Such a memory cell 210 is shown in FIG. 2. Each memory cell 210 includes source region 14 and drain region 16 formed in semiconductor substrate 12, with channel region 18 there between. Floating gate 20 is formed over and insulated from (and controls the conductivity of) a first portion of the channel region 18, and over a portion of the source region 14. Word line terminal 22 (which is typically coupled to a word line) has a first portion that is disposed over and insulated from (and controls the conductivity of) a second portion of the channel region 18, and a second portion that extends up and over the floating gate 20. The floating gate 20 and word line terminal 22 are insulated from the substrate 12 by a gate oxide. Bitline 24 is coupled to drain region 16.

Memory cell 210 is erased (where electrons are removed from the floating gate) by placing a high positive voltage on the word line terminal 22, which causes electrons on the floating gate 20 to tunnel through the intermediate insulation from the floating gate 20 to the word line terminal 22 via Fowler-Nordheim (FN) tunneling.

Memory cell 210 is programmed by source side injection (SSI) with hot electrons (where electrons are placed on the floating gate) by placing a positive voltage on the word line terminal 22, and a positive voltage on the source region 14. Electron current will flow from the drain region 16 towards the source region 14. The electrons will accelerate and become heated when they reach the gap between the word line terminal 22 and the floating gate 20. Some of the heated electrons will be injected through the gate oxide onto the floating gate 20 due to the attractive electrostatic force from the floating gate 20.

Memory cell 210 is read by placing positive read voltages on the drain region 16 and word line terminal 22 (which turns on the portion of the channel region 18 under the word line terminal). If the floating gate 20 is positively charged (i.e., erased of electrons), then the portion of the channel region 18 under the floating gate 20 is turned on as well, and current will flow across the channel region 18, which is sensed as the erased or “1” state. If the floating gate 20 is negatively charged (i.e., programmed with electrons), then the portion of the channel region under the floating gate 20 is mostly or entirely turned off, and current will not flow (or there will be little flow) across the channel region 18, which is sensed as the programmed or “0” state.

Table No. 1 depicts typical voltage and current ranges that can be applied to the terminals of memory cell 210 for performing read, erase, and program operations:

TABLE NO. 1
Operation of Flash Memory Cell 210 of FIG. 2

| | | |
|---|---|---|
| WL | BL | SL |

| | | | | | | |
|---|---|---|---|---|---|---|
| Read | 2-3 | V | 0.6-2 | V | 0 | V |
| Erase | ~11-13 | V | 0 | V | 0 | V |
| Program | 1-2 | V | 10.5-3 | μA | 9-10 | V |

Other split gate memory cell configurations, which are other types of flash memory cells, are known. For example, FIG. 3 depicts a four-gate memory cell 310 comprising source region 14, drain region 16, floating gate 20 over a first portion of channel region 18, a select gate 22 (typically coupled to a word line, WL) over a second portion of the channel region 18, a control gate 28 over the floating gate 20, and an erase gate 30 over the source region 14. This configuration is described in U.S. Pat. No. 6,747,310, which is incorporated herein by reference for all purposes. Here, all gates are non-floating gates except floating gate 20, meaning that they are electrically connected or connectable to a voltage source. Programming is performed by heated electrons from the channel region 18 injecting themselves onto the floating gate 20. Erasing is performed by electrons tunneling from the floating gate 20 to the erase gate 30.

Table No. 2 depicts typical voltage and current ranges that can be applied to the terminals of memory cell 310 for performing read, erase, and program operations:

TABLE NO. 2
Operation of Flash Memory Cell 310 of FIG. 3

| | WL/SG | | BL | | CG | | EG | | SL | |
|---|---|---|---|---|---|---|---|---|---|---|
| Read | 1.0-2 | V | 0.6-2 | V | 0-2.6 | V | 0-2.6 | V | 0 | V |
| Erase | −0.5 V/0 V | | 0 | V | 0 V/−8 V | | 8-12 | V | 0 | V |
| Program | 1 | V | 0.1-1 | μA | 8-11 | V | 4.5-9 | V | 4.5-5 | V |

FIG. 4 depicts a three-gate memory cell 410, which is another type of flash memory cell. Memory cell 410 is identical to the memory cell 310 of FIG. 3 except that memory cell 410 does not have a separate control gate. The erase operation (whereby erasing occurs through use of the erase gate) and read operation are similar to that of the FIG. 3 except there is no control gate bias applied. The programming operation also is done without the control gate bias, and as a result, a higher voltage is applied on the source line during a program operation to compensate for a lack of control gate bias.

Table No. 3 depicts typical voltage and current ranges that can be applied to the terminals of memory cell 410 for performing read, erase, and program operations:

TABLE NO. 3
Operation of Flash Memory Cell 410 of FIG. 4

| | | | |
|---|---|---|---|
| WL/SG | BL | EG | SL |

| | | | | | | | | |
|---|---|---|---|---|---|---|---|---|
| Read | 0.7-2.2 | V | 0.6-2 | V | 0-2.6 | V | 0 | V |

| | | | | | | | |
|---|---|---|---|---|---|---|---|
| Erase | −0.5 V/0 V | 0 | V | 11.5 | V | 0 | V |

| | | | | | | | | |
|---|---|---|---|---|---|---|---|---|
| Program | 1 | V | 0.2-3 | μA | 4.5 | V | 7-9 | V |

FIG. 5 depicts stacked gate memory cell 510, which is another type of flash memory cell. Memory cell 510 is similar to memory cell 210 of FIG. 2, except that floating gate 20 extends over the entire channel region 18, and control gate 22 (which here will be coupled to a word line) extends over floating gate 20, separated by an insulating layer (not shown). The erase is done by FN tunneling of electrons from FG to substrate, programming is by channel hot electron (CHE) injection at region between the channel 18 and the drain region 16, by the electrons flowing from the source region 14 towards to drain region 16 and read operation which is similar to that for memory cell 210 with a higher control gate voltage.

Table No. 4 depicts typical voltage ranges that can be applied to the terminals of memory cell 510 and substrate 12 for performing read, erase, and program operations:

TABLE NO. 4
Operation of Flash Memory Cell 510 of FIG. 5

| | CG | | BL | | SL | Substrate |
|---|---|---|---|---|---|---|
| Read | 2-5 | V | 0.6-2 | V | 0 V | 0 V |
| Erase | −8 to −10 V/0 V | | FLT | | FLT | 8-10 V/15-20 V |
| Program | 8-12 | V | 3-5 | V | 0 V | 0 V |

The methods and means described herein may apply to other non-volatile memory technologies such as FINFET split gate flash or stack gate flash memory, NAND flash, SONOS (silicon-oxide-nitride-oxide-silicon, charge trap in nitride), MONOS (metal-oxide-nitride-oxide-silicon, metal charge trap in nitride), ReRAM (resistive ram), PCM (phase change memory), MRAM (magnetic ram), FeRAM (ferroelectric ram), CT (charge trap) memory, CN (carbon-tube) memory, OTP (bi-level or multi-level one time programmable), and CeRAM (correlated electron ram), without limitation.

In order to utilize the memory arrays comprising one of the types of non-volatile memory cells described above in an artificial neural network, two modifications are made. First, the lines are configured so that each memory cell can be individually programmed, erased, and read without adversely affecting the memory state of other memory cells in the array, as further explained below. Second, continuous (analog) programming of the memory cells is provided.

Specifically, the memory state (i.e., charge on the floating gate) of each memory cell in the array can be continuously changed from a fully erased state to a fully programmed state, and vice-versa, independently and with minimal disturbance of other memory cells. This means the cell storage is effectively analog or at the very least can store one of many discrete values (such as 16 or 64 different values), which allows for very precise and individual tuning of all the memory cells in the memory array, and which makes the memory array ideal for storing and making fine tuning adjustments to the synapsis weights of the neural network.

### Neural Networks Employing Non-Volatile Memory Cell Arrays

FIG. 6 conceptually illustrates a non-limiting example of a neural network utilizing a non-volatile memory array of the present examples. This example uses the non-volatile memory array neural network for a facial recognition application, but any other appropriate application could be implemented using a non-volatile memory array based neural network.

S0 is the input layer, which for this example is a 32×32 pixel RGB image with 5 bit precision (i.e. three 32×32 pixel arrays, one for each color R, G and B, each pixel being 5 bit precision). The synapses CB1 going from input layer S0 to layer C1 apply different sets of weights in some instances and shared weights in other instances and scan the input image with 3×3 pixel overlapping filters (kernel), shifting the filter by 1 pixel (or more than 1 pixel as dictated by the model). Specifically, values for 9 pixels in a 3×3 portion of the image (i.e., referred to as a filter or kernel) are provided to the synapses CB1, where these 9 input values are multiplied by the appropriate weights and, after summing the outputs of that multiplication, a single output value is determined and provided by a first synapse of CB1 for generating a pixel of one of the feature maps of layer C1. The 3×3 filter is then shifted one pixel to the right within input layer S0 (i.e., adding the column of three pixels on the right, and dropping the column of three pixels on the left), whereby the 9 pixel values in this newly positioned filter are provided to the synapses CB1, where they are multiplied by the same weights and a second single output value is determined by the associated synapse. This process is continued until the 3×3 filter scans across the entire 32×32 pixel image of input layer S0, for all three colors and for all bits (precision values). The process is then repeated using different sets of weights to generate a different feature map of layer C1, until all the features maps of layer C1 have been calculated.

In layer C1, in the present example, there are 16 feature maps, with 30×30 pixels each. Each pixel is a new feature pixel extracted from multiplying the inputs and kernel, and therefore each feature map is a two dimensional array, and thus in this example layer C1 constitutes 16 layers of two dimensional arrays (keeping in mind that the layers and arrays referenced herein are logical relationships and may not be physical relationships—i.e., the arrays might not be oriented in physical two dimensional arrays). Each of the 16 feature maps in layer C1 is generated by one of sixteen different sets of synapse weights applied to the filter scans. The C1 feature maps could all be directed to different aspects of the same image feature, such as boundary identification. For example, the first map (generated using a first weight set, shared for all scans used to generate this first map) could identify circular edges, the second map (generated using a second weight set different from the first weight set) could identify rectangular edges, or the aspect ratio of certain features, and so on.

An activation function P1 (pooling) is applied before going from layer C1 to layer S1, which pools values from consecutive, non-overlapping 2×2 regions in each feature map. The purpose of the pooling function P1 is to average out the nearby location (or a max function can also be used), to reduce the dependence of the edge location for example and to reduce the data size before going to the next stage. At layer S1, there are 16 15×15 feature maps (i.e., sixteen different arrays of 15×15 pixels each). The synapses CB2 going from layer S1 to layer C2 scan maps in layer S1 with 4×4 filters, with a filter shift of 1 pixel. At layer C2, there are 22 12×12 feature maps. An activation function P2 (pooling) is applied before going from layer C2 to layer S2, which pools values from consecutive non-overlapping 2×2 regions in each feature map. At layer S2, there are 22 6×6 feature maps. An activation function (pooling) is applied at the synapses CB3 going from layer S2 to layer C3, where every neuron in layer C3 connects to every map in layer S2 via a respective synapse of CB3. At layer C3, there are 64 neurons. The synapses CB4 going from layer C3 to the output layer S3 fully connects C3 to S3, i.e. every neuron in layer C3 is connected to every neuron in layer S3. The output at S3 includes 10 neurons, where the highest output neuron determines the class. This output could, for example, be indicative of an identification or classification of the contents of the original image.

Each layer of synapses is implemented using an array, or a portion of an array, of non-volatile memory cells.

FIG. 7 is a block diagram of an array that can be used for that purpose. Vector-by-matrix multiplication (VMM) array 32 includes non-volatile memory cells and is utilized as the synapses (such as CB1, CB2, CB3, and CB4 in FIG. 6) between one layer and the next layer. Specifically, VMM array 32 includes an array of non-volatile memory cells 33, erase gate and word line gate decoder 34, control gate decoder 35, bit line decoder 36 and source line decoder 37, which decode the respective inputs for the non-volatile memory cell array 33. Input to VMM array 32 can be from the erase gate and wordline gate decoder 34 or from the control gate decoder 35. Source line decoder 37 in this example also decodes the output of the non-volatile memory cell array 33. Alternatively, bit line decoder 36 can decode the output of the non-volatile memory cell array 33.

Non-volatile memory cell array 33 serves two purposes. First, it stores the weights that will be used by the VMM array 32. Second, the non-volatile memory cell array 33 effectively multiplies the inputs by the weights stored in the non-volatile memory cell array 33 and adds them up per output line (source line or bit line) to produce the output, which will be the input to the next layer or input to the final layer. By performing the multiplication and addition function, the non-volatile memory cell array 33 negates the utilization of separate multiplication and addition logic circuits and is also power efficient due to its in-situ memory computation.

The output of non-volatile memory cell array 33 is supplied to a differential summer (such as a summing op-amp or a summing current mirror) 38, which sums up the outputs of the non-volatile memory cell array 33 to create a single value for that convolution. The differential summer 38 is arranged to perform summation of positive weight and negative weight.

The summed-up output values of differential summer 38 are then supplied to an activation function block 39, which rectifies the output. The activation function block 39 may provide sigmoid, tanh, or ReLU functions. The rectified output values of activation function block 39 become an element of a feature map as the next layer (e.g. C1 in FIG. 6), and are then applied to the next synapse to produce the next feature map layer or final layer. Therefore, in this example, non-volatile memory cell array 33 constitutes a plurality of synapses (which receive their inputs from the prior layer of neurons or from an input layer such as an image database), and summing op-amp 38 and activation function block 39 constitute a plurality of neurons.

The input to VMM array 32 in FIG. 7 (WLx, EGx, CGx, and optionally BLx and SLx) can be analog level, binary level, or digital bits (in which case a DAC is provided to convert digital bits to appropriate input analog level) and the output can be analog level, binary level, or digital bits (in which case an output ADC is provided to convert output analog level into digital bits).

FIG. 8 is a block diagram depicting the usage of numerous layers of VMM arrays 32, here labeled as VMM arrays 32a, 32b, 32c, 32d, and 32e. As shown in FIG. 8, the input, denoted Inputx, is converted from digital to analog by a digital-to-analog converter 31 and provided to input VMM array 32a. The converted analog inputs could be voltage or current. The input D/A conversion for the first layer could be done by using a function or a LUT (look up table) that maps the inputs Inputx to appropriate analog levels for the matrix multiplier of input VMM array 32a. The input conversion could also be done by an analog to analog (A/A) converter to convert an external analog input to a mapped analog input to the input VMM array 32a.

The output generated by input VMM array 32a is provided as an input to the next VMM array (hidden level 1) 32b, which in turn generates an output that is provided as an input to the next VMM array (hidden level 2) 32c, and so on. The various layers of VMM array 32 function as different layers of synapses and neurons of a convolutional neural network (CNN). Each VMM array 32a, 32b, 32c, 32d, and 32e can be a stand-alone, physical non-volatile memory array, or multiple VMM arrays could utilize different portions of the same physical non-volatile memory array, or multiple VMM arrays could utilize overlapping portions of the same physical non-volatile memory array. The example shown in FIG. 8 contains five layers (32a, 32b, 32c, 32d, 32e): one input layer (32a), two hidden layers (32b, 32c), and two fully connected layers (32d,32e). One of ordinary skill in the art will appreciate that this is merely an example and that a system instead could comprise more than two hidden layers and more than two fully connected layers.

Each non-volatile memory cell used in a neural network is erased and programmed to hold a very specific and precise amount of charge, i.e., the number of electrons, in the floating gate. For example, each floating gate holds one of N different values, where N is the number of different weights that can be indicated by each cell. Examples of N include 16, 32, 64, 128, and 256.

One challenge of implementing a neural network using analog memory cells is that extreme precision is desired for read operations as each floating gate in each cell may be intended to hold one of N values, where N is greater than the conventional value of 2 used in conventional flash memory systems. However, the characteristics of each device, such as its current-voltage response characteristic curve, will change as its operating temperature changes. For example, the current drawn by a memory cell when operating in the sub-threshold region changes exponentially as its operating temperature changes.

What is needed is a system for improved operation of an array of non-volatile memory cells in a neural network that compensates for changes in operating conditions.

### SUMMARY OF THE INVENTION

Numerous examples are disclosed for of a bias circuit and method for a non-volatile memory array in a neural network.

In one example, a system comprises an array of non-volatile memory cells arranged in rows and columns, wherein each non-volatile memory cell comprises a word line terminal and a bit line terminal; and a row circuit to receive a row address and a bias voltage and to output the bias voltage when the row address corresponds to a row of the array associated with the row circuit, wherein the bias voltage is provided to terminals of non-volatile memory cells in the row of the array associated with the row circuit.

In another example, a method comprises receiving, by a row decoder coupled to an array of non-volatile memory cells arranged in rows and columns, a row address and a bias voltage; outputting, by the row decoder, the bias voltage when the row address corresponds to a row of the array associated with the row decoder; and applying, by the row decoder the bias voltage to terminals of non-volatile memory cells in the row of the array associated with the row decoder.

In another example, a method comprises applying a bias voltage to a terminal of a selected non-volatile memory cell; activating a transistor comprising a first terminal coupled to a bit line terminal of the selected non-volatile memory cell and a second terminal; and generating a voltage at the second terminal of the transistor indicating a value stored in the selected non-volatile memory cell.

### BRIEF DESCRIPTION OF THE DRAWINGS

FIG. 1 is a diagram that illustrates a prior art artificial neural network.

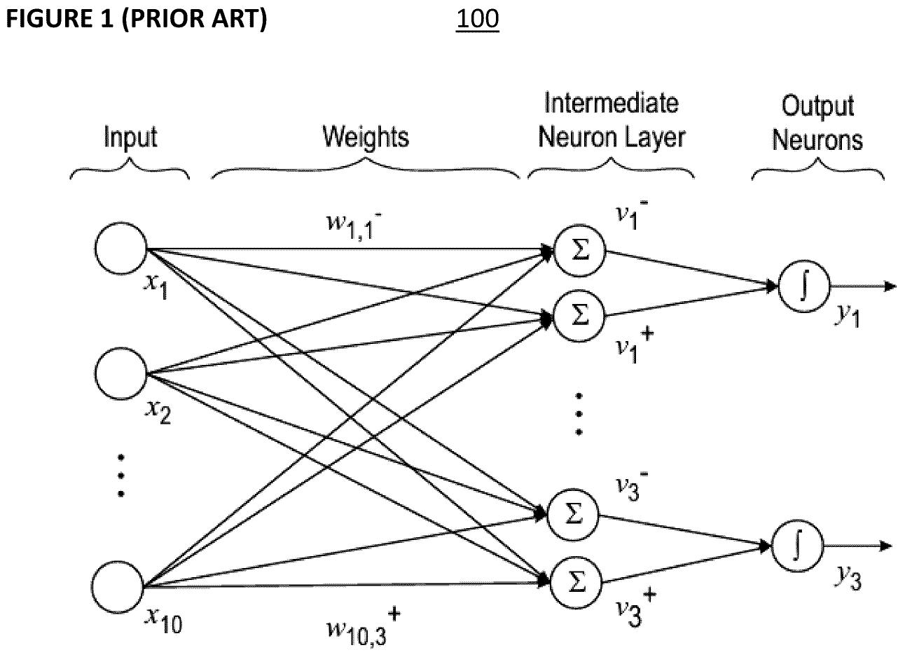

FIG. 2 is a cross-sectional side view of a conventional 2-gate non-volatile memory cell.

FIG. 3 is a cross-sectional side view of a conventional 4-gate non-volatile memory cell.

FIG. 4 is a side cross-sectional side view of conventional 3-gate non-volatile memory cell.

FIG. 5 is a cross-sectional side view of another conventional 2-gate non-volatile memory cell.

FIG. 6 is a diagram illustrating the different levels of an example artificial neural network utilizing a non-volatile memory array.

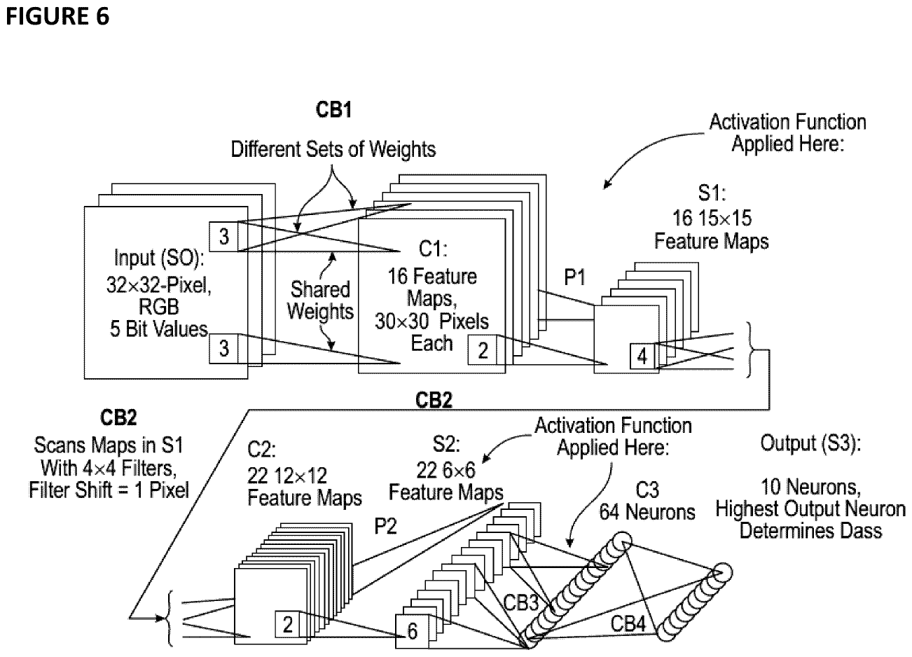

FIG. 7 is a block diagram illustrating a vector multiplier matrix.

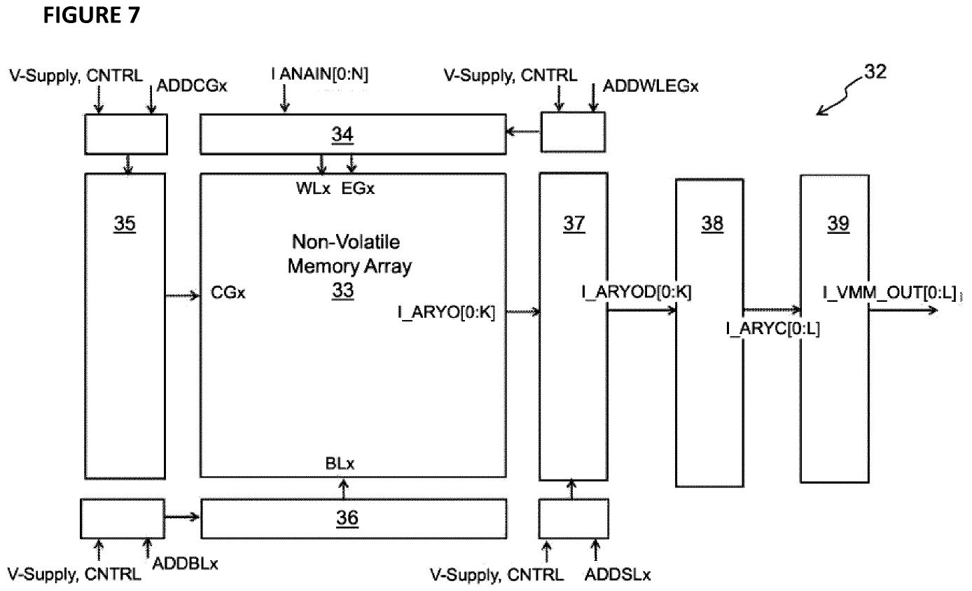

FIG. 8 is a block diagram illustrating various levels of a vector multiplier matrix.

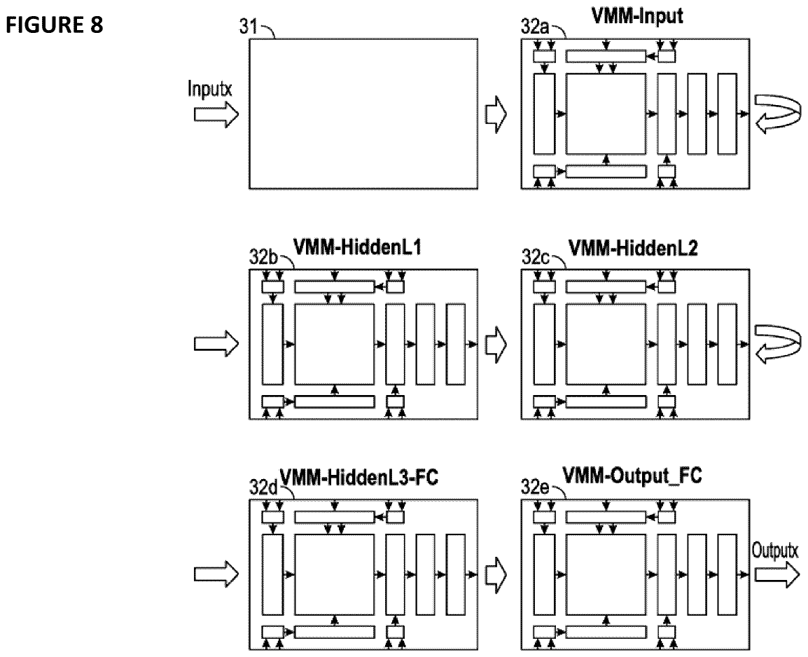

FIG. 9 is a block diagram of a VMM system.

FIG. 10 depicts an input circuit for a VMM system.

FIG. 11 depicts a global digital-to-analog circuit used in the input circuit of FIG. 10.

FIG. 12 depicts an output circuit for a VMM system.

FIG. 13 depicts a word line bias application circuit and output circuit.

FIG. 14 depicts a word line bias generation circuit.

FIG. 15 depicts another word line bias generation circuit.

FIG. 16 depicts another word line bias generation circuit.

FIG. 17 depicts a method for applying a bias voltage to word line terminals of a row of non-volatile memory cells in an array.

FIG. 18 depicts a CGEG bias generation circuit.

### DETAILED DESCRIPTION OF THE INVENTION

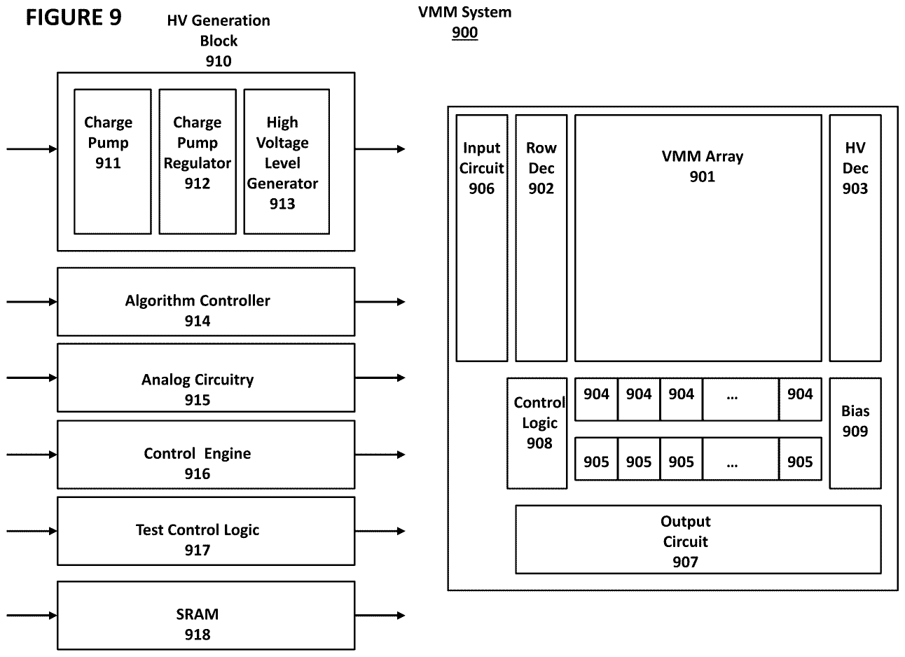

FIG. 9 depicts a block diagram of VMM system 900. VMM system 900 comprises VMM array 901, row decoder 902, high voltage decoder 903, column decoders 904, bit line drivers 905 (such as bit line control circuitry for programming), input circuit 906, output circuit 907, control logic 908, and bias generator 909. VMM system 900 further comprises high voltage generation block 910, which comprises charge pump 911, charge pump regulator 912, and high voltage level generator 913. VMM system 900 further comprises (program/erase, or weight tuning) algorithm controller 914, analog circuitry 915, control engine 916 (that may include functions such as arithmetic functions, activation functions, embedded microcontroller logic, without limitation), test control logic 917, and static random access memory (SRAM) block 918 to store intermediate data such as for input circuits (e.g., activation data) or output circuits (neuron output data, partial sum output neuron data) or data in for programming (such as data in for a whole row or for multiple rows).

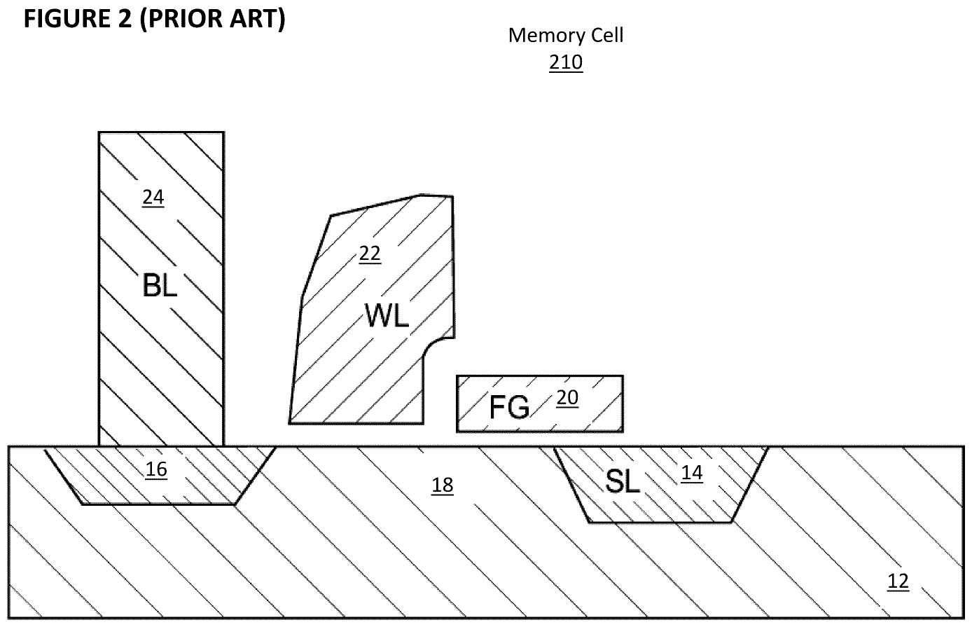

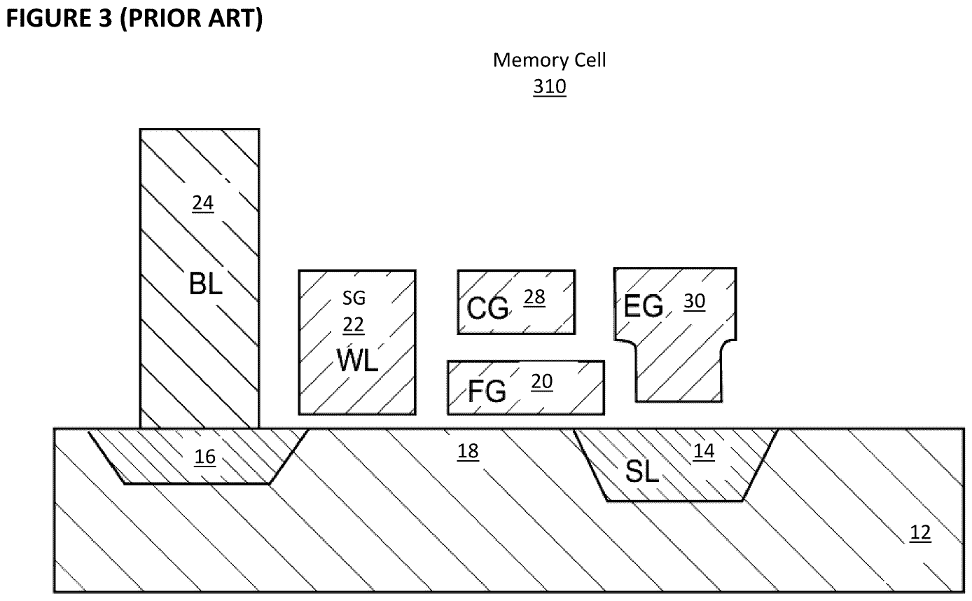

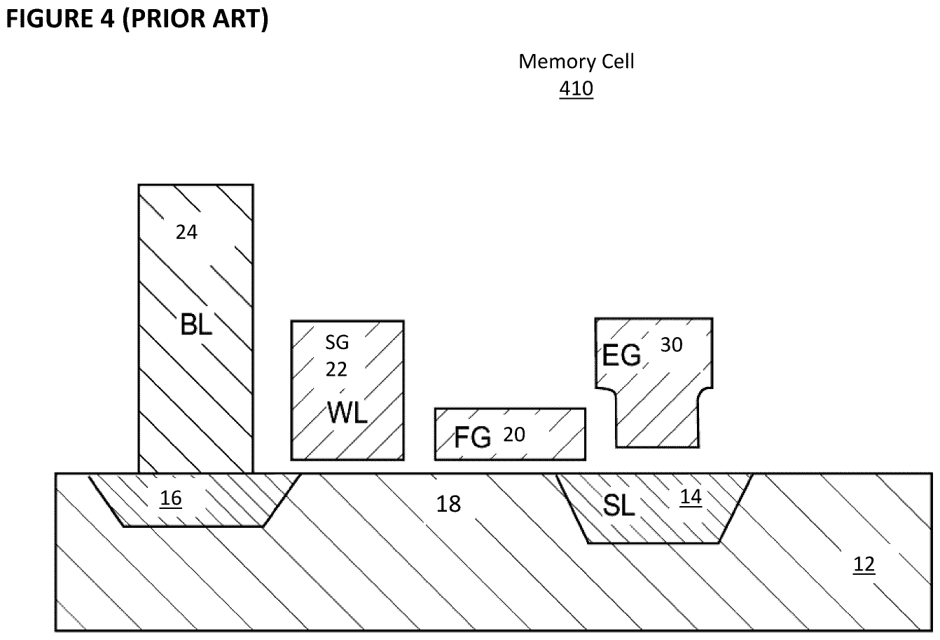

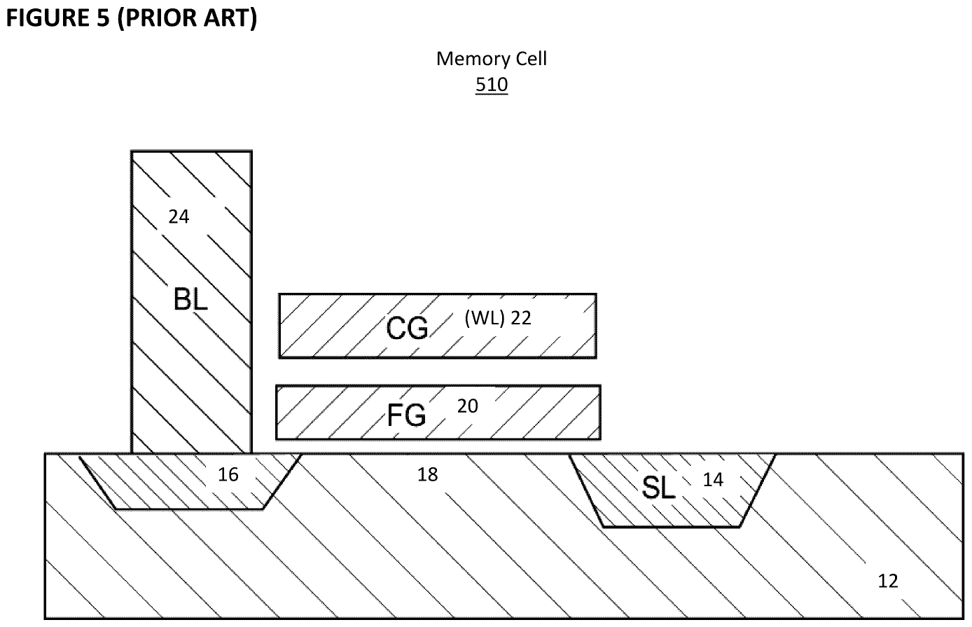

VMM array 901 comprises an array of non-volatile memory cells arranges in rows and columns. In one example, the memory cells of VMM array 901 comprise split-gate flash memory cells such as cells based on the design of memory cell 210, 310, or 410 in FIGS. 2, 3, and 4, respectively. In another example, the memory cells of VMM array 901 comprise stacked-gate flash memory cells such as cells based on the design of memory cell 510 in FIG. 5.

The input circuit 906 may include circuits such as a DAC (digital to analog converter), DPC (digital to pulses converter, digital to time modulated pulse converter), AAC (analog to analog converter, such as a current to voltage converter, logarithmic converter), PAC (pulse to analog level converter), or any other type of converters. The input circuit 906 may implement one or more of normalization, linear or non-linear up/down scaling functions, or arithmetic functions. The input circuit 906 may implement a temperature compensation function for input levels. The input circuit 906 may implement an activation function such as ReLU or sigmoid. Input circuit 906 may store digital activation data to be applied as, or combined with, an input signal during a program or read operation. The digital activation data can be stored in registers. Input circuit 906 may comprise circuits to drive the array terminals, such as CG, WL, EG, and SL lines, which may include sample-and-hold circuits and buffers. A DAC can be used to convert digital activation data into an analog input voltage to be applied to the array.

The output circuit 907 may include circuits such as an ITV (current-to-voltage circuit), ADC (analog to digital converter, to convert neuron analog output to digital bits), AAC (analog to analog converter, such as a current to voltage converter, logarithmic converter), APC (analog to pulse(s) converter, analog to time modulated pulse converter), or any other type of converters. The output circuit 907 may convert array outputs into activation data. The output circuit 907 may implement an activation function such as rectified linear activation function (ReLU) or sigmoid. The output circuit 907 may implement one or more of statistic normalization, regularization, up/down scaling/gain functions, statistical rounding, or arithmetic functions (e.g., add, subtract, divide, multiply, shift, log) for neuron outputs. The output circuit 907 may implement a temperature compensation function for neuron outputs or array outputs (such as bitline output) so as to keep power consumption of the array approximately constant or to improve precision of the array (neuron) outputs such as by keeping the IV slope approximately the same over temperature. The output circuit 907 may comprise registers for storing output data.

In the examples discussed below, parameters of input circuit 906 and output circuit 907 may be configured depending on the type of neural network being implemented (for example, an MLP, CNN, RNN, or other type of network), the nature of the layer being implemented (for example, the first layer, a middle layer, or the last layer), on neural CNN operation being performed (for example, depthwise, 1D, or 2D), on the filter size or kernel size (for example, 3×3, 1×1, 7×7, or other size), on the channel depth (for example, 32, 64, 128, or another size).

Within output circuit 907, ITVs can be configured per network layer to receive different input ranges and produce a constant array output which is used by the ADC to produce, for example, an 8-bit output. A resistor-based ITV (R-ITV) can be adjusted by changing one or more resistor values. A capacitor-based ITV (C-ITV) can be adjusted by changing one or more capacitor values or the integration time. ADCs can be configured per network layer to receive different input ranges from the ITV and produce a constant resolution such as an 8-bit output, A current mirror also can be used to mirror the array output with an adjustable ratio, Adjusting ITVs, ADCs, and current mirrors make it possible to implement a wide range of VMM outputs.

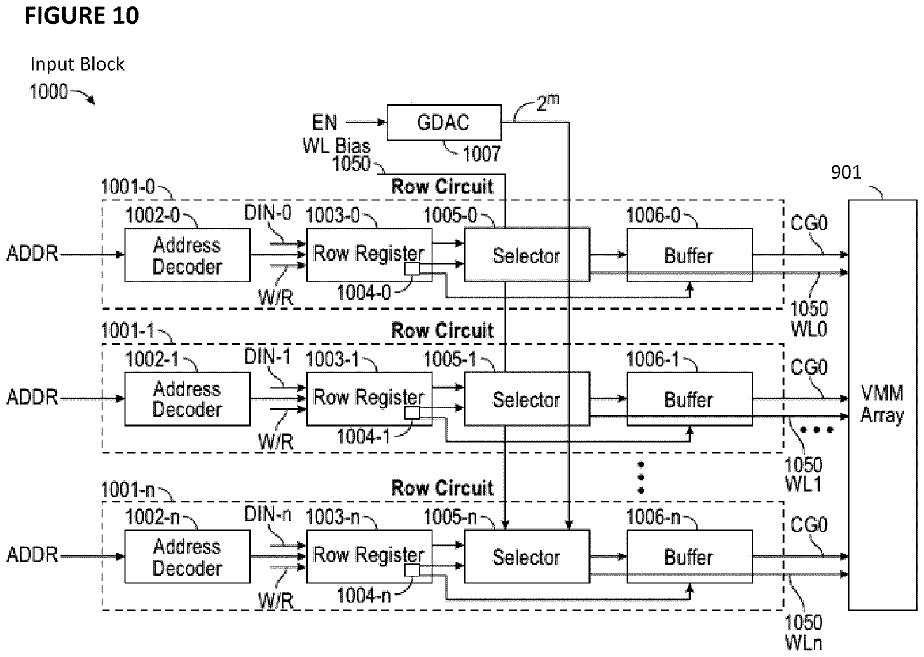

FIG. 10 depicts an example of components that can be used in input circuit 906 of FIG. 9 for purposes of applying input values to rows of VMM array 901 as well as a bias voltage to control gate terminals and word line terminals of the rows during a read operation, where the input values will be multiplied by weights stored in cells of VMM array 901 and each column of VMM array 901 will generate an output current representing a sum of the products of each cell in the column multiplied by the input value received by that cell.

FIG. 10 depicts input block 1000. Input block 1000 comprises row circuits 1001-0, 1001-1, . . . , 1001-n, where n+1 is the number of rows in VMM array 901, and global digital-to-analog converter (GDAC) 1007. VMM array 901 is shown for clarity, but VMM array 901 is not part of input block 1000. Input block 1000 is an example implementation of input circuit 906 in FIG. 9.

Row circuit 1001-0 is an input circuit that generates, and applies, output CG0 and WL0 to the control gate line and word line, respectively, of row 0 of non-volatile memory cells in VMM array 901; row circuit 1001-1 is an input circuit that generates, and applies, output CG1 and WL1 to the control gate line and word line, respectively of row 1 of non-volatile memory cells in VMM array 901; row circuit 1001-n is an input circuit that generates, and applies, output CGn and WLn to the control gate line and word line, respectively, of row n of non-volatile memory cells in VMM array 901; and all other row circuits 1001 have the same role as to an associated row in VMM array 901.

Row circuit 1001-0 comprises address decoder 1002-0, row register 1003-0, tag bit 1004-0, selector 1005-0, and buffer 1006-0. Similarly, row circuit 1001-1 comprises address decoder 1002-1, row register 1003-1, tag bit 1004-1, selector 1005-1, and buffer 1006-1; row circuit 1001-n comprises address decoder 1002-n, row register 1003-n, tag bit 1004-n, selector 1005-n, and buffer 1006-n; and all other row circuits 1001 have the same structure.

Each row circuit 1001 operates in the same manner. The load and read operations will be described as to row circuit 1001-0 but it is to be understood that this explanation applies to all other row circuits 1001 as well.

During a load operation, the W/R port on row register 1003-0 receives a value indicating a write operation (e.g., “0”) and row register 1003-0 is loaded with input data comprising m bits of data. For example, m might be 8, 16, 32, 64, 128, 256, or another other number. The input data to be loaded can be activation data or input data such as from an object or image that is to be classified or recognized by a neural network application. Address decoder 1002-0 receives an address, ADDR. If ADDR matches the address associated with row 0, address decoder 1002-0 asserts its output signal, which is provided to row register 1003-0. Row register 1003-0, in response to the asserted output signal of address decoder 1002-0, performs a load operation and stores the received data-in, DIN-0. The loaded data is used in a subsequent read or verify operation.

Row register 1003-0 also stores tag bit 1004-0, which tag bit 1004-0 can be used to enable or disable row 0, such as by disabling the output of selector 1005-0 or buffer 1006-0, regardless of whether the row is selected or not selected by address decoder 1002. For example, if tag bit 1004-0 has a certain value (e.g., “1”), the activation data in row register 1003-0 will be output when ADDR indicates that row 0 is selected. If tag bit 1004-0 has a different value (e.g., “0”), the activation data in row register 1003-0 will not be output because, for example, the tag bit value will disable the output of row register 1003-0, selector 1005-0 (for example, by serving as an input to an enable port), or buffer 1006-0 (for example, by serving as an input to an enable port,). and a default value (e.g., “0”) will instead be output even when ADDR indicates that row 0 is selected. Tag bits 1004 can be useful, for example, to save power when a controller (not shown) determines that a read operation can be skipped. When row register 1003-0 is not disabled by tag bit 1004-0, it will output the data that was stored in it during the load operation when address decoder 1002-2 asserts its output in response to receiving the address ADDR that corresponds to row 0.

During a read or verify operation, address decoder 1002-0 receives an address, ADDR. If ADDR matches the address associated with row 0, address decoder 1002-0 asserts its output signal, which is provided to row register 1003-0. The W/R port on row register 1003-0 receives a value indicating a read operation (e.g., “1”) and row register 1003-0, in response to the asserted output signal of address decoder 1002-0, outputs its stored data, DIN-0 if its tag bit 1004-0 is a value (e.g., “1”) that enables the output of data.

GDAC 1007 receives an enable signal, EN, and when enabled, outputs 2^{m} different analog voltages on 2^{m} different output lines, where the 2^{m} different analog voltages represent the set of possible analog voltages that can be applied to a control gate line in VMM array 901. Selector 1005 receives a value from row register 1003-0 (which can be “0” if ADDR is not the address corresponding to row 0, if tag bit 1004-0 was a value that does not enable the output of data, or if the stored activation data in row register 1003-0 is “0”; and which otherwise will be the value stored in row register 1003-0). Selector 1005-0 receives all 2′ lines from GDAC 1007 and selects a particular line based on the m bit value received from row register 1003-0. The analog voltage from the selected line from GDAC 1007 is then provided to buffer 1006-0, which will then provide a buffered version of the received analog voltage (i.e., the buffered version of the received analog voltage will not substantially vary based on the input impedance or capacitance of VMM array 901) to the control gate line CG0 of VMM array 901. Selectors 1005 also receive word line bias 1050 (or alternatively, a control gate bias) and provide it to word lines WL0, WL1, . . . , WLn of associated rows in VMM array 901.

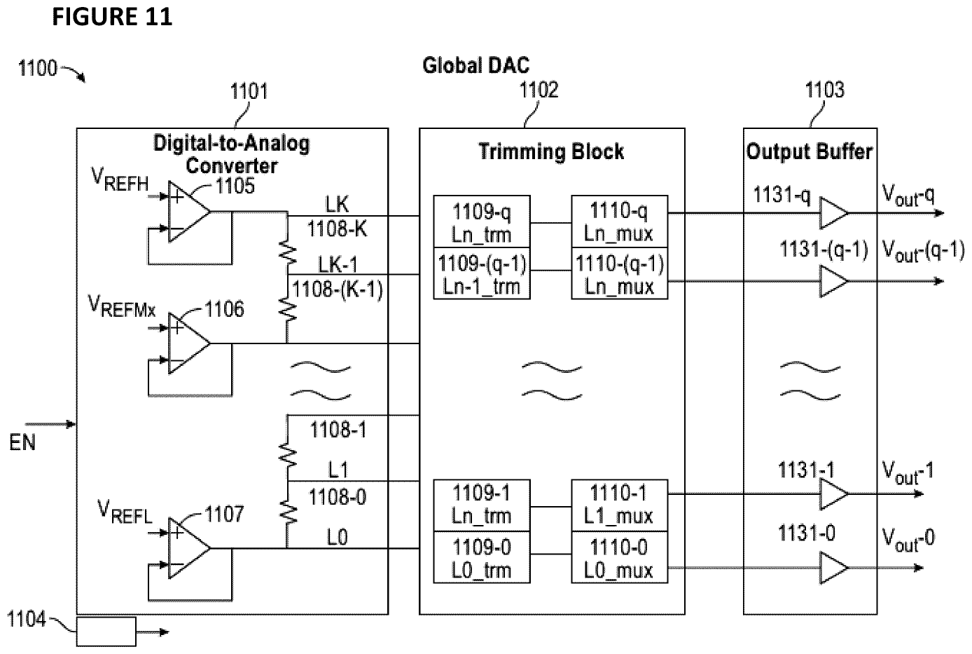

FIG. 11 depicts global digital-to-analog converter 1100, which can be used as GDAC 1007 in FIG. 10. Global digital-to-analog converter 1100 comprises digital-to-analog converter 1101, trimming block 1102, and output buffer 1103. Control logic 1104 controls the operation of global digital-to-analog converter 1100, such as by enabling various blocks using enable signals (e.g., EN), providing control signals to multiplexors, and generating other control signals.

DAC 1101 receives a high reference voltage (VREFH), a medium reference voltage (VREFMx), and a low reference voltage, VREFL, provided to voltage buffers 1105, 1106, and 1107, respectively. Reference voltages VREFH/VREFM/VREFL are generated by a reference circuit. The values of reference voltages VREFH, VREFM, VREFL are determined in response to the maximum current level, medium current level, and low current level corresponding to the operation cell current range of VMM array 901, for example, from 0-100 nA. Additional other reference voltages can be used, such as reference voltages with values between VREFL and VREFM and between VREFM and VREFH.

DAC 1101 comprises a voltage ladder comprising a plurality of resistors 1108-0, 1108-1, . . . , 1108-(k−1), 1108-k that are used to generate a range of voltages (L0, L1, . . . , L(k−1), Lk) between VREFH and VREFMx and between VREFMx and VREFL, optionally according to a linear function, a logarithmic function or a customized logarithmic function (e.g., where the memory cell operates in the sub-threshold region). For example, the top node of the top resistor 1108-k in the voltage ladder will have a voltage Lk equal to VREFH, and the bottom node of the bottom resistor 1108-0 in the voltage ladder will have a voltage L0 equal to VREFL, with intermediate nodes having voltages between VREFH and VREFL based on the voltage drop across resistors above and below the node. The voltage ladder thereby generates a plurality of voltage levels (L0, . . . , Lk) (for example, k might be 4095), which are used when it is desired to provide a voltage to a VMM array to cause the non-volatile memory cells of the VMM array to operate in linear mode or sub-threshold mode. VREFM can be chosen so that DAC 1101 simulates cell behavior.

Trimming block 1102 receives q+1 voltages from digital-to-analog converter. Trimming block 1102 comprises sub blocks 1109-0, 1109-1, . . . , 1109-(q−1), 1109-q and multiplexors 1110-0, 1110-1, . . . , 1110-(q−1), and 1110-q. Thus, trimming block 1102 comprises (q+1) trim blocks 1109 and (q+1) multiplexors 1110. Trimming block 1102 performs local trimming on each of the q+1 voltage levels. This may be useful, for example, when the non-volatile memory cells in the array are operating in the sub-threshold region. This is desirable to achieve a good matching I-V slope for the non-volatile memory cells in the VMM array over temperature in sub threshold region or linear region.

By adjusting reference voltages VREFL, VREFM, and VREFH, the k+1 levels are adjusted as well. This is, for example, to match the output range of this input block with an input range of the memory cells. This is also for temperature compensation by adjusting (such as shifting lower at high temperature and higher at lower temperature) the reference levels VREFL and VREFH to match that of the gate bias of the memory cells over temperature. Further individual voltage level adjustment and temperature compensation is done by trimming circuits of trimming block 1102.

The output from multiplexors 1110 is provided to output buffer 1103, which provides output voltages VOUT-0 to VOUT-q, where (q+1)=2^{m}. For example, if m=4, (q+1)=16, meaning that global DAC 1100 will generate 16 different voltage outputs. Output buffer 1103 comprises buffers 1131-0, 1131-1, . . . , 1131-(q−1), 1131-q.

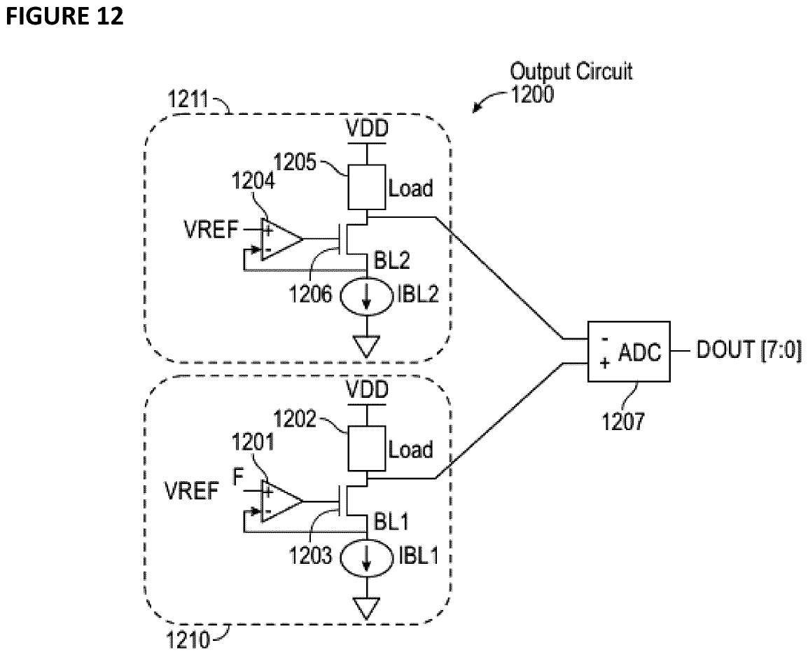

FIG. 12 depicts output circuit 1200, which can be used for two columns in output circuit 907 in FIG. 9. Output circuit 1200 is used to read a value stored in differential memory cells coupled to a first bit line and a second bit line in an array of memory cells, where IBL1 is the current drawn by the first bit line coupled to a first column of cells in the array and IBL2 is the current drawn by the second bit line coupled to a second column of cells in the array and generate differential digital output bits by a differential ADC.

Read circuit 1200 comprises current-to-voltage converter 1210 (a first current-to-voltage converter), current-to-voltage converter 1211 (a second current-to-voltage converter), and differential ADC 1207 (which can be a SAR ADC or other type of ADC).

Current-to-voltage converter 1210 comprises operational amplifier 1201 (a first operational amplifier) (or an equivalent regulating circuit), load 1202 (a first load, which can comprise one or more resistors, capacitors, or transistors), and NMOS transistors 1203 (a first transistor). Load 1202 comprises a first terminal coupled to a voltage source VDD and a second terminal. NMOS transistor 1203 comprises a first terminal coupled to the second terminal of load 1202, a gate, and a second terminal coupled to the first bit line. Operational amplifier 1201 comprises an inverting input coupled to the first bit line, an inverting input coupled to VREF1 (a first reference voltage) and an output coupled to the gate of NMOS transistor 1203.

Current-to-voltage converter 1211 comprises operational amplifier 1204 (a second operation amplifier) (or an equivalent regulating circuit), load 1205 (a second load, which can comprise one or more resistors, capacitors, or transistors), and NMOS transistor 1206 (a second transistor). Load 1205 comprises a first terminal coupled to a voltage source VDD and a second terminal. NMOS transistor 1206 comprises a first terminal coupled to the second terminal of load 1205, a gate, and a second terminal coupled to the second bit line. Operational amplifier 1204 comprises an inverting input coupled to the second bit line, an inverting input coupled to VREF2 (a second reference voltage, which can be the same or different than VREF1) and an output coupled to the gate of NMOS transistor 1203.

As an example, using a 12.5 kΩ resistor for loads 1202 and 1205 will generate currents of approximately 25 uA into the terminals of NMOS transistors 1203 and 1206, respectively.

ADC 1207 comprises a first input coupled to the second terminal of the first load, a second input coupled to the second terminal of the second load, and an output to generate a set of output bits.

Thus, the non-inverting inputs of operational amplifiers 1201 and 1204 are each coupled to a reference voltage Vref, and the source of regulating transistors 1206 and 1203 are connected to the inverting input of operational amplifiers 1204 and 1201, respectively. The source voltage of transistors 1206 and 1203 are thus driven to be equal to VREF, meaning voltages of BL1 and BL2 coupled to the selected cells are driven to VREF voltage). Here, the voltages provided to the inverting and non-inverting terminals of ADC 1207 are referenced with respect to the supply voltage, VDD, and are the result of voltage drops from the supply voltage in amounts equal to the currents IBL2 and IBL1 through loads 1205 and 1202, respectively. The output of the ADC effectively implements W=W+−W−.

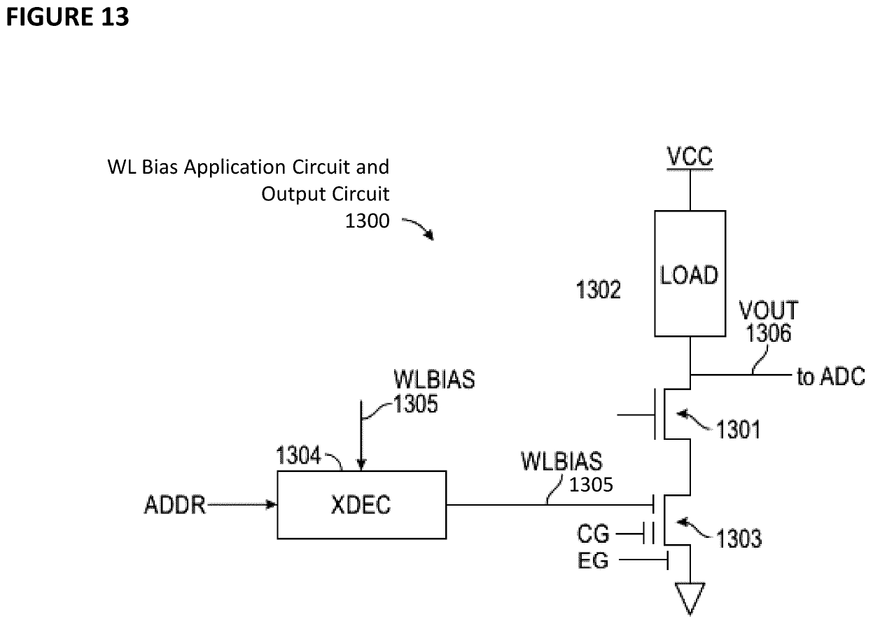

FIG. 13 depicts word line bias application circuit and output circuit 1300 coupled to selected memory cell 1303. Selected memory cell 1303 is not part of word line bias application circuit and output circuit 1300 but is shown for illustration purposes. Selected memory cell 1303 can be part of VMM array 901 in FIG. 9.

Word line bias application circuit and output circuit 1300 comprises a select transistor 1301 (which, to reduce the amount of die space needed for word line bias application circuit and output circuit, can be part of a column multiplexor, such as column decoder 904 in FIG. 9, used to select a bitline within VMM array 901), load 1302, and row decoder 1304. Load 1302 can comprise one or more resistors, capacitors, and transistors. To reduce the amount of die space needed for word line bias application circuit and output circuit, load 1302 optionally can be one or more devices contained in a current-to-voltage converter in the sensing circuit.

Row decoder 1304 is an example implementation of a row decoder 902 in FIG. 9.

Selected memory cell 1303 is coupled to row decoder 1304. During operation, row decoder 1304 receives a row address, ADDR, and a voltage, WLBIAS 1305. WLBIAS 1305 is an example of WL Bias 1050 in FIG. 10. WLBIAS 1305 is an adaptable bias voltage that changes in response to changes in PVT (process, voltage, and temperature) to keep Vds (the drain-to-source voltage of the transistor formed by the floating gate) in selected memory cell 1303 approximately constant as PVT changes.

The transistor formed by the wordline terminal of selected memory cell 1303 serves as a cascoding transistor where the voltage of its gate, which is WLBIAS 1305, varies as temperature changes to keep the source of that transistor at a constant voltage. This transistor serves as a source-follower transistor where the voltage of its gate changes as temperature changes to keep the voltage of its source constant.

Row decoder 1304 outputs the tracking bias voltage WLBIAS 1305 when the row address, ADDR, corresponds to the address associated with the row containing selected memory cell 1303. WLBIAS 1305 is provided in that instance to the word line terminal of selected memory cell 1303, which then begins to draw current during a read operation. Load 1302 provides a voltage drop from VCC in proportion to the current drawn by selected memory cell 1303 to generate an output voltage, VOUT 1306, which is a voltage representing the read value of selected memory cell 1303. VOUT 1306 optionally can then be converted into digital form by an analog-to-digital converter (not shown). Because WLBIAS 1305 changes in response to changes in PVT, VOUT 1306 also will change in response to changes in PVT.

Alternatively, WLBIAS 1305 can be replaced by a control gate bias voltage signal that is applied to the control gate terminal of selected memory cell 1303.

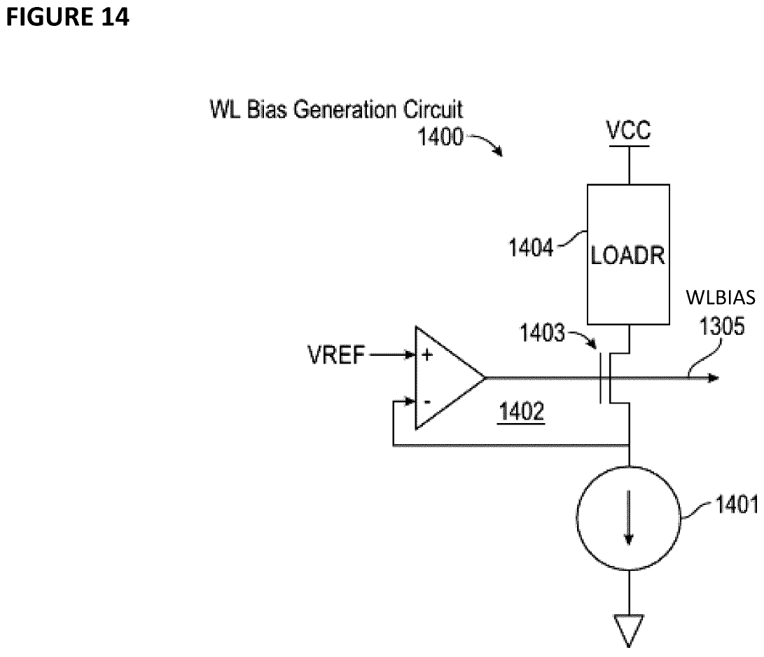

FIG. 14 depicts word line bias generation circuit 1400, which is an example of a circuit to generate WLBIAS 1305 (or, alternatively, a control gate bias) used in FIG. 13. Word line bias generation circuit 1400 comprises current source 1401, operational amplifier 1402, select transistor 1403, and dummy load 1404.

Load 1404 comprises a first terminal coupled to a voltage source, VCC, and a second terminal. Load 1404 can comprise one or more resistors, capacitors, and transistors. To reduce the amount of die space needed for word line bias application circuit and output circuit, dummy load 1404 optionally can be one or more devices contained in a current-to-voltage converter in the sensing circuit.

Select transistor 1403 comprises a first terminal coupled to the second terminal of dummy load 1404, a gate, and a second terminal. Select transistor 1403 is designed to track the transistors formed by word line terminals of memory cells in VMM array 901 such that changes in PVT affect select transistor 1403 in the same manner as the memory cells. For instance, select transistor 1403 might have a similar size and transistor type as to the word line transistor in the memory cells in VMM array 901.

Current source 1401 comprises a first terminal coupled to the second terminal of select transistor 1403 and a second terminal coupled to ground. Current source 1401 is designed to provide a fixed current (similar to current values in memory cells in VMM array 901) or to vary its current as operating temperature changes to track the temperature changes of the currents in in VMM array 901.

Operational amplifier 1402 comprises a non-inverting input terminal coupled to a reference voltage, VREF, an inverting input terminal coupled to the second terminal of select transistor 1403, and an output coupled to the gate of select transistor 1403 and to an output of the word line bias generation circuit, wherein the output of the word line bias generation circuit provides WLBIAS 1305, a bias voltage. The voltage of the terminal of select transistor 1403 coupled to load 1404 varies based on the current drawn by current source 1401, which in turn varies in response to operating temperature. Thus, WLBIAS 1305 changes as PVT, including operating temperature, changes. The purpose of the circuit is to impose a fixed bias voltage on the source of the transistor 1403 as PVT changes. Because the WLBIAS voltage 1305 is applied to wordline terminals of memory cells, the source of the transistor formed by the WL terminal in the memory cells will have similar voltage as the source of the transistor 1403, meaning that the Vds of the FG transistor of each memory cell is kept at a rather fixed voltage, in this case, Vds FG=˜VREF.

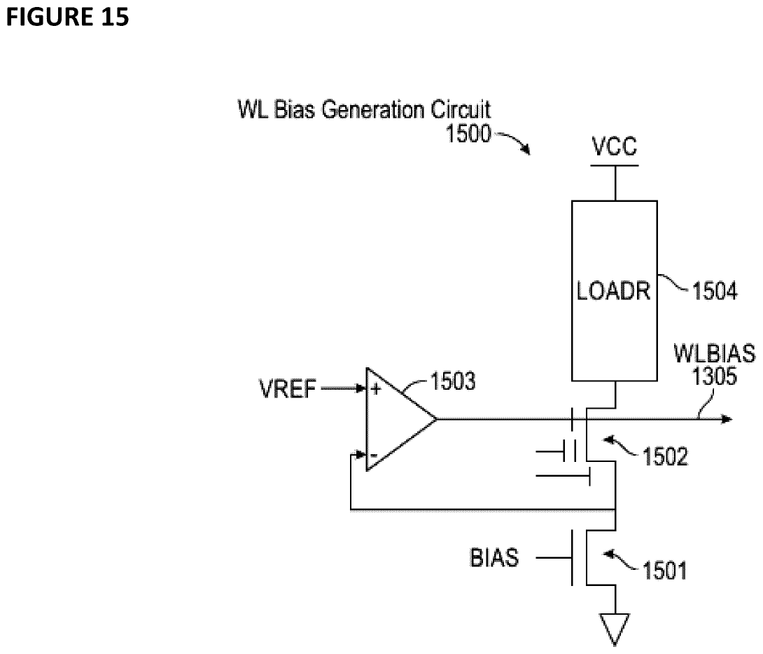

FIG. 15 depicts word line bias generation circuit 1500, which is an example of a circuit to generate WLBIAS 1305 (or, alternatively, a control gate bias) used in FIG. 13. Word line bias generation circuit 1500 comprises select transistor 1501, reference memory cell 1502, operational amplifier 1503, and load 1504. Reference memory cell 1502 optionally is part of the same array, VMM array 901 in FIG. 9, containing the selected memory cells of interest or is part of the same die as VMM array 901. For this reason, word line bias generation circuit 1500 can be referred to as a replica bias circuit.

Load 1504 comprises a first terminal coupled to a voltage source, VCC, and a second terminal. Load 1504 can comprise one or more resistors, capacitors, and transistors. To reduce the amount of die space needed for word line bias application circuit and output circuit, load 1504 optionally can be one or more devices contained in a current-to-voltage converter in the sensing circuit.

Reference memory cell 1502 comprises a bit line terminal coupled to the second terminal of load 1504, a word line terminal, and a source line terminal. Transistor 1501 comprises a first terminal coupled to the source line terminal of reference memory cell 1502, a gate coupled to a control signal, BIAS, and a second terminal coupled to ground. Transistor 1501 emulates the current in memory cells in VMM array.

Operational amplifier 1503 comprises a non-inverting input terminal coupled to a reference voltage, VREF, an inverting input terminal coupled to the source line terminal of reference memory cell 1502, and an output coupled to the word line terminal of reference memory cell 1502 and to an output of word line bias generation circuit 1500, wherein the output of the word line bias generation circuit provides WLBIAS 1305, a bias voltage. The reference memory cell 1502 is deeply erased (such that it conducts strongly) so that its VDS voltage drop is insignificant. Hence, the source of the wordline transistor of the reference memory cell 1502 is maintained an approximately constant voltage, e.g., VREF, over PVT.

The wordline transistor of the reference memory cell 1502 serves to track the wordline transistors of memory cells in VMM array. Thus, WLBIAS 1305, which is applied to wordlines of selected memory cells through wordline bias application circuit and output circuit 1300, changes as operating temperature changes to keep Vds FG of selected memory cells constant, e.g., =VREF. Because the WLBIAS voltage 1305 is applied to wordline terminals of memory cells, the source of the WL transistor in the memory cells will have similar voltage as the source of the transistor 1501, meaning that the Vds of the FG transistor of each memory cell is kept at a rather fixed voltage, in this case, Vds FG=˜VREF.

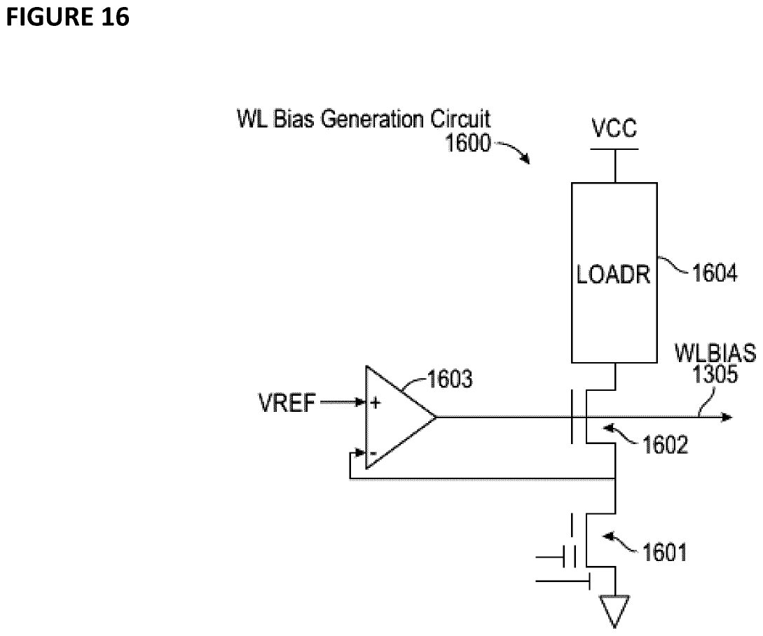

FIG. 16 depicts word line bias generation circuit 1600, which is an example of a circuit to generate WLBIAS 1305 (or, alternatively, a control gate bias) used in FIG. 13. Word line bias generation circuit 1600 comprises select transistor 1602, reference memory cell 1601, operational amplifier 1603, and load 1604. Reference memory cell 1601 optionally is part of the same array, VMM array 901 in FIG. 9, containing the selected memory cells of interest or is part of the same die as VMM array 901. For this reason, word line bias generation circuit 1600 can be referred to as a replica bias circuit.

Load 1604 can comprise one or more resistors, capacitors, and transistors. To reduce the amount of die space needed for word line bias application circuit and output circuit, load 1604 optionally can be one or more devices contained in a current-to-voltage converter in the sensing circuit. Load 1604 comprises a first terminal coupled to a voltage source, VCC, and a second terminal.

Select transistor 1602 comprises a first terminal coupled to the second terminal of load 1604, a gate, and a second terminal. Select transistor 1602 is designed to track the wordline transistors in memory cells.

Reference memory cell 1601 comprises a bit line terminal coupled to the second terminal of select transistor 1602 and a source line terminal coupled to ground. The reference memory cell 1601 serves as the current load for the select transistor 1602 and it is similar the memory cells in VMM array for purpose of tracking between the current load and the currents in array memory cells.

Operational amplifier 1603 comprises a non-inverting input terminal coupled to a reference voltage, VREF, an inverting input terminal coupled to the bit line terminal of reference memory cell 1601, and an output coupled to the gate of select transistor 1602 and to an output of the word line bias generation circuit 1600, wherein the output of the word line bias generation circuit 1600 provides WLBIAS 1305, a bias voltage. Thus, WLBIAS 1305, which is applied to wordlines of selected memory cells through wordline bias application circuit and output circuit 1300, changes as operating temperature changes to impose an approximately constant Vds FG voltage, e.g. =VREF. Because the WLBIAS voltage 1305 is applied to wordline terminals of memory cells, the source of the WL transistor in the memory cells will have similar voltage as the source of the select transistor 1602, meaning that the Vds of the FG transistor of each memory cell is kept at a rather fixed voltage, in this case, Vds FG=˜VREF.

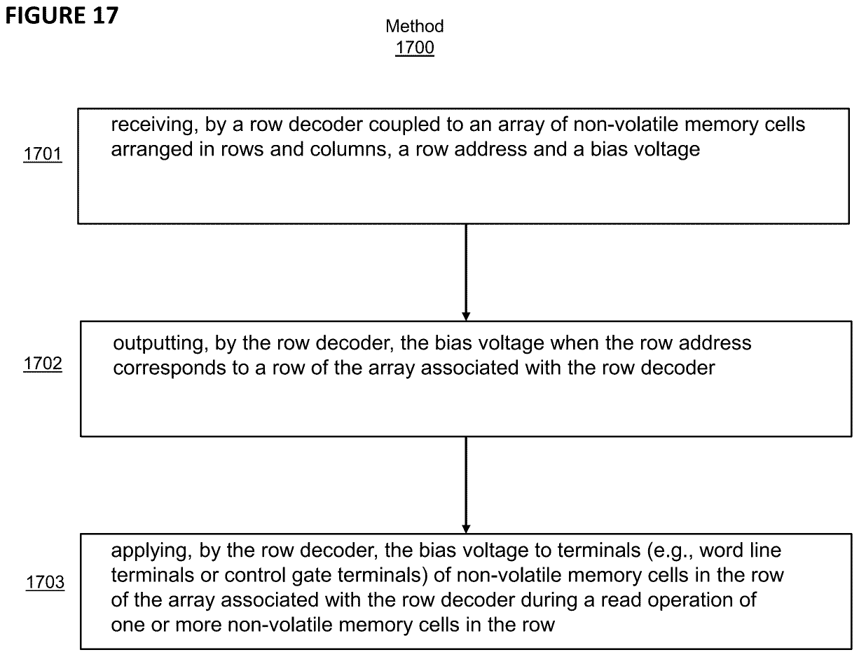

FIG. 17 depicts method 1700 for applying a bias voltage to terminals of a row of cells in an array of non-volatile memory cells. Method 1700 comprises receiving, by a row decoder coupled to an array of non-volatile memory cells arranged in rows and columns, a row address and a bias voltage (1701); outputting, by the row decoder, the bias voltage when the row address corresponds to a row of the array associated with the row decoder (1702); and applying, by the row decoder, the bias voltage to terminals (e.g., word line terminals or control gate terminals) of non-volatile memory cells in the row of the array associated with the row decoder during a read operation of one or more non-volatile memory cells in the row (1703).

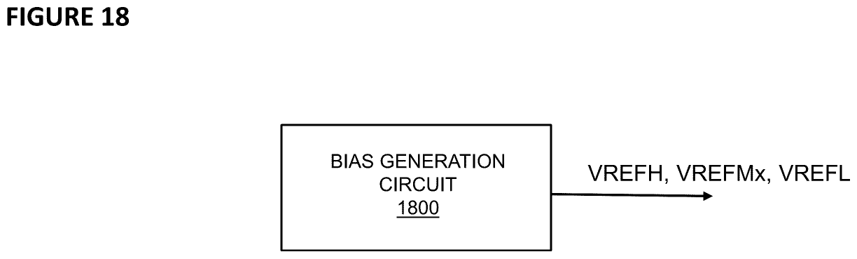

FIG. 18 depicts bias generation circuit 1800 that generates the bias voltages used for one or more of VREFH, VREFMx, and VREFL for global DAC 1100 in FIG. 11. These bias voltages are temperature compensated. Bias generation circuit 1800 can comprise one or more of the circuits disclosed in FIGS. 23-29 of U.S. Pat. No. 10,755,783 and FIG. 18 of U.S. patent application Ser. No. 18/367,921, which are incorporated by reference herein.

It is to be noted that, as used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements there between.

What is claimed is:

1. A system comprising:
an array of non-volatile memory cells arranged in rows and columns, wherein each non-volatile memory cell comprises a word line terminal and a bit line terminal; and
a row circuit to receive a row address and a bias voltage and to output the bias voltage when the row address corresponds to a row of the array associated with the row circuit, wherein the bias voltage is provided to terminals of non-volatile memory cells in the row of the array associated with the row circuit.

2. The system of claim 1, wherein the terminals are word line terminals.

3. The system of claim 1, wherein the terminals are control gate terminals.

4. The system of claim 1, wherein the row circuit receives the row address during a read operation of one or more non-volatile memory cells in the row of the array associated with the row circuit.

5. The system of claim 1, wherein the row circuit receives the row address during a verify operation of one or more non-volatile memory cells in the row of the array associated with the row circuit.

6. The system of claim 1, wherein the bias voltage is generated by a word line bias generation circuit.

7. The system of claim 6, wherein the word line bias generation circuit comprises:
a load comprising a first terminal coupled to a voltage source and a second terminal;
a select transistor comprising a first terminal coupled to the second terminal of the load, a gate, and a second terminal;
a current source comprising a first terminal coupled to the second terminal of the select transistor and a second terminal coupled to ground; and
an operational amplifier comprising a non-inverting input terminal coupled to a reference voltage, an inverting input terminal coupled to the second terminal of the select transistor, and an output coupled to the gate of the select transistor and to an output of the word line bias generation circuit, wherein the output of the word line bias generation circuit provides the bias voltage.

8. The system of claim 7, wherein the load comprises one or more resistors, capacitors, and transistors.

9. The system of claim 6, wherein the word line bias generation circuit comprises:
a load comprising a first terminal coupled to a voltage source and a second terminal;
a reference memory cell comprising a bit line terminal coupled to the second terminal of the load, a word line terminal, and a source line terminal;
a select transistor comprising a first terminal coupled to the source line terminal of the reference memory cell, a gate coupled to a control signal, and a second terminal coupled to ground; and
an operational amplifier comprising a non-inverting input terminal coupled to a reference voltage, an inverting input terminal coupled to the source line terminal of the reference memory cell, and an output coupled to the word line terminal of the reference memory cell and to an output of the word line bias generation circuit, wherein the output of the word line bias generation circuit provides the bias voltage.

10. The system of claim 9, wherein the load comprises one or more resistors, capacitors, and transistors.

11. The system of claim 6, wherein the word line bias generation circuit comprises:
a load comprising a first terminal coupled to a voltage source and a second terminal;
a select transistor comprising a first terminal coupled to the second terminal of the load, a gate, and a second terminal;
a reference memory cell comprising a bit line terminal coupled to the second terminal of the select transistor and a source line terminal coupled to ground; and
an operational amplifier comprising a non-inverting input terminal coupled to a reference voltage, an inverting input terminal coupled to the bit line terminal of the reference memory cell, and an output coupled to the gate of the select transistor and to an output of the word line bias generation circuit, wherein the output of the word line bias generation circuit provides the bias voltage.

12. The system of claim 11, wherein the load comprises one or more resistors, capacitors, and transistors.

13. A method comprising:
receiving, by a row decoder coupled to an array of non-volatile memory cells arranged in rows and columns, a row address and a bias voltage;
outputting, by the row decoder, the bias voltage when the row address corresponds to a row of the array associated with the row decoder; and
applying, by the row decoder the bias voltage to terminals of non-volatile memory cells in the row of the array associated with the row decoder.

14. The method of claim 13, wherein the terminals are word line terminals.

15. The method of claim 13, wherein the terminals are control gate terminals.

16. The method of claim 15, wherein the bias voltage causes voltages of drains of floating gate transistors of the non-volatile memory cells in the row of the array associated with the row decoder to be approximately constant as temperature, process, or power supply changes.

17. The method of claim 15, wherein the bias voltage is generated by a replica bias circuit.

18. The method of claim 17, wherein the replica bias circuit comprises a reference memory cell originated from a same process as non-volatile memory cells in the array.

19. A method comprising:
applying a bias voltage to a terminal of a selected non-volatile memory cell;
activating a transistor comprising a first terminal coupled to a bit line terminal of the selected non-volatile memory cell and a second terminal; and
generating a voltage at the second terminal of the transistor indicating a value stored in the selected non-volatile memory cell.

20. The method of claim 19, wherein the terminal of the selected non-volatile memory cell is a word line terminal.

21. The method of claim 19, wherein the terminal of the selected non-volatile memory cell is a control gate terminal.

22. The method of claim 21, wherein the bias voltage changes in response to a change in temperature to maintain an approximately constant drain-to-source voltage of the selected non-volatile memory cell.

23. The method of claim 21, wherein the transistor and the selected non-volatile memory cell form a source-follower configuration.

24. The method of claim 21, wherein the second terminal of the transistor is coupled to a load.

25. The method of claim 24, wherein the load comprises one or more resistors, capacitors, and transistors.

26. The method of claim 24, wherein the load is coupled to a voltage source.
